(19) United States
(12) Patent Application Publication
(10) Pub. No.: US 2017/0260630 A1
(43) Pub. Date: Sep. 14, 2017

(54) SUBSTRATE PROCESSING APPARATUS AND SUBSTRATE PROCESSING METHOD

(71) Applicant: SUMITOMO CHEMICAL COMPANY, LIMITED, Tokyo (JP)

(72) Inventors: Hajime FUJIKURA, Hitachi-shi (JP); Taichiro KONNO, Hitachi-shi (JP); Takehiro NONAKA, Hitachi-shi (JP); Takayuki NUMATA, Hitachi-shi (JP)

(73) Assignee: SUMITOMO CHEMICAL COMPANY, LIMITED, Tokyo (JP)

(21) Appl. No.: 15/532,015

(22) PCT Filed: Dec. 17, 2015
(86) PCT No.: PCT/JP2015/085364

§ 371 Date: May 31, 2017

(30) Foreign Application Priority Data
Dec. 19, 2014 (JP) 2014-256951

(51) Int. Cl. C23C 16/455; C30B 31/14; H01L 29/207; H01L 21/02; H01L 29/20; C30B 25/12; C30B 29/40

(52) U.S. Cl. CPC C23C 16/45593; C30B 25/12; C30B 31/14; C30B 29/406; H01L 21/0254; H01L 21/02576; H01L 29/2003; H01L 29/207; H01L 21/0262

(57) ABSTRACT

There is provided a technique of suppressing unintended substrate processing from being performed after predetermined substrate processing is ended, including a substrate support section that supports a substrate in a processing chamber; a processing gas supply section that supplies a processing gas into the processing chamber; and a moving mechanism that moves the substrate support section in the processing chamber, between a first position to which the processing gas supplied from the processing gas supply section is blown, and a second position to which the processing gas supplied from the processing gas supply section is not blown.

### TECHNICAL FIELD

The present invention relates to a substrate processing apparatus and a substrate processing method.

### DESCRIPTION OF RELATED ART

A conventionally proposed substrate processing apparatus includes: a processing chamber in which a substrate is processed; a substrate support section that supports the substrate in the processing chamber; a processing gas supply section that supplies a processing gas generated by making a metal source react with a reaction gas, to the substrate in the processing chamber (for example, see patent document 1).

### PRIOR ART DOCUMENT

### Patent Document

Patent document 1: Japanese Patent Laid Open Publication No. 2013-58741

### SUMMARY OF THE INVENTION

### Problem to be Solved by the Invention

However, in the abovementioned substrate processing apparatus, even after supply of the processing gas from the processing gas supply section into the processing chamber is stopped, the processing gas remained in the processing gas supply section or the like is blown to the substrate in the processing chamber in some cases. Namely, after supply of the processing gas from the processing gas supply section into the processing chamber is stopped, unintended substrate processing is performed in some cases.

In order to solve the abovementioned problem, an object of the present invention is to provide a technique of suppressing unintended substrate processing from being performed after predetermined substrate processing is ended.

### Means for Solving the Problem

According to an aspect of the present invention, there is provided a substrate processing apparatus, including:

a processing chamber in which a substrate is processed;

a substrate support section that supports the substrate in the processing chamber;

a processing gas supply section that supplies a processing gas into the processing chamber; and

a moving mechanism that moves the substrate support section in the processing chamber, between a first position to which the processing gas supplied from the processing gas supply section is blown, and a second position to which the processing gas supplied from the processing gas supply section is not blown.

According to other aspect of the present invention, there is provided a substrate processing method, including a step of:

processing a substrate in a processing chamber,

wherein in the step of processing the substrate, substrate processing is performed by blowing a processing gas from the processing gas supply section, to the substrate that exists at a first position to which a processing gas is blown, the processing gas being supplied into the processing chamber from a processing gas supply section, and

substrate processing is ended by moving a substrate support section supporting the substrate using a moving mechanism, to a second position to which the processing gas is not blown, the processing gas being supplied into the processing chamber from the processing gas supply section.

### Advantage of the Invention

According to the present invention, it is possible to provide a technique of suppressing unintended substrate processing from being performed after predetermined substrate processing is ended.

### BRIEF DESCRIPTION OF THE DRAWINGS

FIG. 1 is a vertical cross-sectional schematic view of a substrate processing apparatus according to an embodiment of the present invention.

FIG. 2 is a graph showing a relationship between a distance from a surface of a GaN film formed by using the substrate processing apparatus according to an embodiment of the present invention and Si-concentration as an impurity.

### DETAILED DESCRIPTION OF THE INVENTION

### Knowledge Obtained by Inventors of the Present Invention

Prior to a description of an embodiment of the present invention, explanation will be given for a knowledge obtained by inventors of the present invention. As a substrate processing apparatus, there is a substrate processing apparatus including a processing gas generator that generates a processing gas for performing substrate processing by making a liquid source react with a reaction gas, the liquid source being generated by melting a metal source under a high temperature atmosphere, for example. Such a substrate processing apparatus performs substrate processing by supplying the processing gas into a processing chamber from the processing gas generator while generating the processing gas in the processing gas generator, and blowing the processing gas to the substrate in the processing chamber.

However, in such substrate processing apparatus, even when predetermined substrate processing is ended (for example, after elapse of the time for predetermined substrate processing) and supply of the reaction gas into the processing gas generator is ended, the reaction gas is remained in the processing gas generator. Generally substrate processing is ended by switching the gas supplied into the processing gas generator from the reaction gas (a gas including the reaction gas) to a gas not containing the reaction gas (purge gas such as hydrogen (H₂) gas or nitrogen (N₂) or a mixed gas of them). However, at a time point of the switching of gases, the reaction gas is remained in the processing gas generator. Therefore, even after supply of the reaction gas into the processing gas generator is stopped, the processing gas is continuously generated in the processing gas generator due to the reaction gas remained in the processing gas generator, and the processing gas is continuously supplied into the processing chamber in some cases. As a result, even after a time point when the processing is intended to be ended, the processing gas is continuously blown to the substrate in the processing chamber, and unintended substrate processing is performed to an already processed substrate in some cases.

Further, usually, after supply of the reaction gas into the processing gas generator is stopped, the gas not containing the reaction gas is continuously supplied to the processing gas generator, and therefore a concentration of the processing gas generated in the processing gas generator is gradually lowered. Namely, after supply of the reaction gas into the processing gas generator is stopped, supply conditions of the processing gas supplied into the processing chamber are varied (changed) in some cases.

When unintended substrate processing is performed to the already processed substrate after predetermined substrate processing is ended, a composition is varied and a quality of a surface of the substrate is changed in some cases. For example, by performing unintended substrate processing, a transition layer in which a composition in a thickness direction of a film and a thickness of the film and the like are not constant, is formed on the already processed substrate in some cases.

As a method for preventing such an unintended substrate processing, it is conceivable to use a method of stopping supply of all gases such as the reaction gas and a gas not containing the reaction gas into the processing gas generator at the end of substrate processing, and in this state, cooling the substrate processing apparatus including the processing gas generator to a temperature at which the substrate can be taken out. However, such a method has some disadvantages, so it is difficult to adopt this method.

First, due to cooling, the gas remained in the processing gas generator contracts (volumetrically contracts), and therefore the processing gas remained in the processing chamber is sucked into the processing gas generator in some cases. For example, in a case of performing substrate processing of forming a gallium nitride (GaN) film on a substrate by making gallium chloride (GaCl) gas generated in the processing gas generator react with ammonia (NH₃) gas in the processing chamber, NH₃ gas is sucked into the processing gas generator in some cases. Thereby, GaCl gas and NH₃ gas are reacted with each other in the processing gas generator, and a GaN film (GaN crystal) is deposited in the processing gas generator in some cases. For example, the GaN film is deposited on an outlet port which is provided to the processing gas generator for discharging GaCl gas, resulting in blocking the outlet port in some cases.

Secondly, when the substrate processing apparatus including the processing gas generator is cooled without supplying a purge gas into the processing gas generator, for purging an inside of the processing gas generator during cooling of the inside of the processing gas generator, there is a risk that the reaction gas (for example, HCl gas) used for generating GaCl gas and remained in the processing gas generator, leaks out of the processing chamber when the substrate is taken out from the processing chamber.

The present invention is provided, in order to solve a problem that occurs for example in the following case. After supply of the reaction gas into the processing gas generator is stopped, the processing gas is continuously generated in the processing gas generator due to the reaction gas remained in the processing gas generator, and the processing gas is continuously supplied into the processing chamber.

### An Embodiment of the Present Invention

### (1) Configuration of the Substrate Processing Apparatus

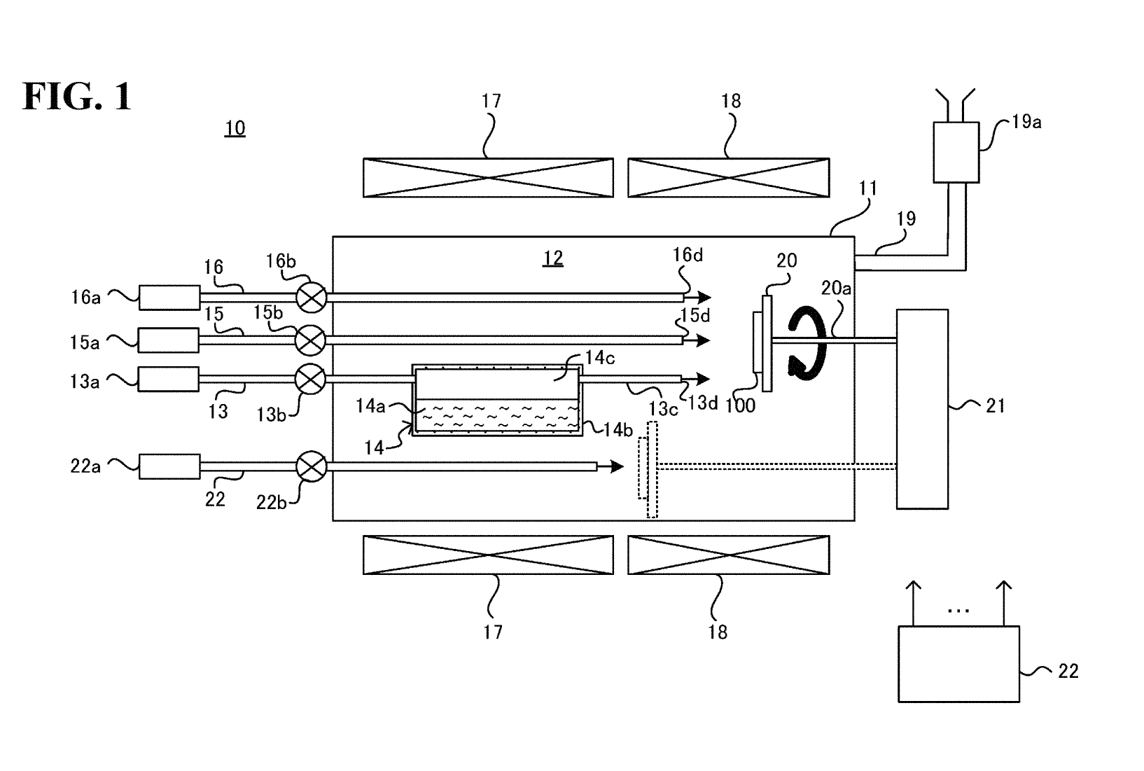

A substrate processing apparatus according to an embodiment of the present invention will be described hereafter, with reference to mainly FIG. 1. In this embodiment, explanation will be given for a case in which the substrate processing apparatus is a Hydride Vapor Phase Epitaxy apparatus (HVPE apparatus) as an example.

As shown in FIG. 1, the HVPE apparatus as a substrate processing apparatus 10 includes a reaction vessel 11 made of a heat resistant material such as quartz (SiO₂), for example. A processing chamber 12 is formed in a hollow cylinder portion in the reaction vessel 11.

A reaction gas supply pipe 13 is airtightly provided to the reaction vessel 11 so as to penetrate through a side portion of the reaction vessel 11. The reaction gas supply pipe 13 is made of a metal material (for example, stainless-steel) or a nonmetal material (for example, quartz) having heat resistance, corrosion resistance, and the like.

On the outside of the reaction vessel 11 in the reaction gas supply pipe 13, a reaction gas supply source 13a and a valve 13b as a valve for suppling/stopping the reaction gas to a processing gas generator 14 described later, are provided in this order from an upstream side. For example, chlorine (Cl₂) gas or hydrogen chloride (HCl) gas is supplied as the reaction gas from the reaction gas supply pipe 13 into the processing gas generator 14. A first processing gas supply pipe 13c that supplies a processing gas (first processing gas) generated in the processing gas generator 14 to a substrate 100 for performing processing to the substrate 100, is formed in the processing gas generator 14. The first processing gas supply pipe 13c is made of a nonmetal material (for example, quartz) having heat resistance, corrosion resistance, and the like. A first processing gas supply port 13d is formed at a downstream end portion (downstream end) of the first processing gas supply pipe 13c. A group III element-containing gas (for example, GaCl gas) is supplied as a first processing gas from the first processing gas supply pipe 13c into the processing chamber 12 through the first processing gas supply port 13d, and is blown to the substrate 100 that exists at a first position described later.

The processing gas generator 14 is provided in the reaction vessel 11. The processing gas generator 14 includes a vessel 14b to store a metal source 14a therein. A space 14c through which the reaction gas passes is formed above the metal source 14a in the vessel 14b. The processing gas generator 14 is configured so that when the reaction gas passes through the space 14c, the reaction gas is brought into contact with the metal source 14a so that the reaction gas and the metal source 14a are reacted with each other, to thereby generate the processing gas (first processing gas).

The vessel 14b is formed so that its planar shape is a rectangular shape, for example. The vessel 14b is made of a nonmetal material (for example, high purity quartz) having heat resistance and corrosion resistance. From a viewpoint of reducing a replenishment frequency of the metal source and maintaining a high purity of the metal source 14a, it is preferable to make a volume of the vessel 14b as large as possible. A downstream end of the reaction gas supply pipe 13 is airtightly connected to the vessel 14b, and an upstream end of the abovementioned first processing gas supply pipe 13c is airtightly connected thereto.

As the metal source 14a, for example, a source which is solid at ordinary temperature is used. For example, as the metal source 14a, gallium (Ga) solid, indium (In) solid, or aluminum (Al) solid which is a metal source containing a group III element is used. Depending on a temperature in the processing gas generator 14 and a used metal, the metal source 14a may be in a solid state or in a liquid state.

A volume of the vessel 14b is preferably, for example, 0.5 liter (0.5 L) to 3 L. Further, an amount of the metal source (for example, Ga) to be put (supplemented) in the vessel 14b is preferably, for example, about 10% to 80% of the volume of the vessel 14b. When the volume of the vessel 14b is, for example, 2 L, it is preferable that Ga, which is a metal source of 50% of the volume of an inside of the vessel 14b, is put into the vessel 14b, to thereby set the volume of the space 14c to 1 L.

A first processing gas supply section is mainly composed of the reaction gas supply pipe 13, the valve 13b, the processing gas generator 14, and the first processing gas supply pipe 13c. It is conceivable that the reaction gas supply source 13a is included in the first processing gas supply section.

A second processing gas supply pipe 15 is airtightly provided to the reaction vessel 11 so as to penetrate through the side portion of the reaction vessel 11. The second processing gas supply pipe 15 is made of a metal material (for example, stainless-steel) or a nonmetal material (for example, quartz) having heat resistance, corrosion resistance, and the like.

On the outside of the reaction vessel 11 in the second processing gas supply pipe 15, a second processing gas supply source 15a and a valve 15b as a valve for supplying/stopping the second processing gas to the substrate 100 in the processing chamber 12, are provided in this order from an upstream side. A second processing gas supply port 15d is formed at a downstream end portion (downstream end) of the second processing gas supply pipe 15. A group V element-containing gas (for example, NH₃ gas) is supplied as a second processing gas from the second processing gas supply pipe 15 into the processing chamber 12 through the second processing gas supply port 15d, and is blown to the substrate 100 that exists at the first position described later.

A second processing gas supply section is mainly composed of the second processing gas supply pipe 15 and the valve 15b. It is conceivable that the second processing gas supply source 15a is included in the second processing gas supply section.

The processing gas supply section is mainly composed of the first processing gas supply section and the second processing gas supply section.

Further, a doping gas supply pipe 16 is airtightly provided to the reaction vessel 11 so as to penetrate through the side portion of the reaction vessel 11. The doping gas supply pipe 16 is made of a metal material (for example, stainless-steel) or a nonmetal material (for example, quartz) having heat resistance, corrosion resistance, and the like.

On the outside of the reaction vessel 11 in the doping gas supply pipe 16, a doping gas supply source 16a and a valve 16b as a valve for supplying/stopping the doping gas to the substrate 100 in the processing chamber 12, are provided in this order from an upstream side. A doping gas supply port 16d is formed at a downstream end portion (downstream end) of the doping gas supply pipe 16. Si element-containing gas such as dichlorosilane (SiH₂Cl₂) gas is supplied as a doping gas for an impurity to be doped from the doping gas supply pipe 16 into the processing chamber 12 through the doping gas supply port 16d, and is blown to the substrate 100 that exists at the first position described later.

A doping gas supply section is mainly composed of the doping gas supply pipe 16 and the valve 16b. It is conceivable that the doping gas supply source 16a is included in the doping gas supply section. It is also conceivable that the doping gas supply section is included in the processing gas supply section.

On the outer periphery of the reaction vessel 11, a first heater 17 and a second heater 18 are provided as a heating section. An inside of the processing gas generator 14 is heated to a predetermined temperature (for example, 500° C. to 900° C.) mainly by the first heater 17. The substrate 100 that exists at the first position in the processing chamber 12 described later is heated to a predetermined temperature (for example, 500° C. to 1200° C.) mainly by the second heater 18.

An exhaust pipe 19 for exhausting an atmosphere in the processing chamber 12 is airtightly provided to the reaction vessel 11. A vacuum pump (or a blower) 19a as an exhaust device is provided on the exhaust pipe 19 in some cases.

A susceptor 20 as a substrate support section for supporting the substrate 100 in the processing chamber 12 is provided in the processing chamber 12. A rotating shaft 20a is provided on the susceptor 20, and the susceptor 20 is configured to be rotatable.

A moving mechanism 21 is provided to the susceptor 20, so as to be capable of moving the susceptor 20 in the processing chamber 12 while holding the susceptor 20 in a state of airtightly maintaining an inside of the processing chamber 12.

Specifically, the moving mechanism 21 is configured so that the susceptor 20 supporting the substrate 100 can be moved between the first position in the processing chamber 12 to which the processing gas supplied from the processing gas supply section is blown, and the second position (for example the position indicated by a broken line in FIG. 1) in the processing chamber 12 to which the processing gas supplied from the processing gas supply section is not blown.

When substrate processing is performed, the moving mechanism 21 moves the susceptor 20, for example so that the substrate 100 supported by the susceptor 20 is positioned at the first position. Further, when substrate processing is not performed (for example when predetermined substrate processing is ended), the moving mechanism 21 moves the susceptor 20, for example so that the substrate 100 supported by the susceptor 20 is positioned at the second position.

After elapse of the time for predetermined substrate processing, it is preferable that the moving mechanism 21 moves the susceptor 20 supporting the substrate 100 to the second position from the first position, before supply of the first processing gas from the first processing gas supply section into the processing chamber 12 is stopped.

After elapse of the time for predetermined substrate processing, it is further preferable that the moving mechanism 21 moves the susceptor 20 supporting the substrate 100 to the second position from the first position, before supply conditions are varied, such as a concentration, a composition, and a supply amount of the first processing gas supplied from the first processing gas supply section into the processing chamber 12.

It is further preferable that the moving mechanism 21 moves the susceptor 20 supporting the substrate 100 to the second position from the first position, at the moment when supply of the reaction gas to the processing gas generator 14 is stopped (at the same time as the stop) or before supply of the reaction gas into the processing gas generator 14 is stopped.

As described above, after predetermined substrate processing is ended (for example, after elapse of the time for predetermined substrate processing), by moving the susceptor 20 supporting the substrate 100 to the second position from the first position using the moving mechanism 21, it is possible to suppress unintended substrate processing performed to the already processed substrate 100.

Preferably, the first position exists, for example, on a flow path of the processing gas flowing through the processing chamber 12 from the processing gas supply section toward the exhaust pipe 19. Further, preferably the first position exists, for example, on a downstream side of the first processing gas supply port 13d, the second processing gas supply port 15d, and the doping gas supply port 16d. Further, preferably the second position exists, for example, on an upstream side of the first processing gas supply port 13d, the second processing gas supply port 15d, and the doping gas supply port 16d. The second position includes not only a position to which the processing gas (the first processing gas, the second processing gas, and the doping gas) are not blown at all, but also a position to which these processing gases are blown to the extent that substrate processing (for example film formation) is not performed.

The movement of the susceptor 20 by the moving mechanism 21 can be controlled, for example, through a controller 22 electrically connected to the moving mechanism 21.

Further, a protective gas blowing pipe 22 for blowing a protective gas for protecting the surface of the substrate 100, to the substrate 100 (the already processed substrate 100) that has moved to the second position, is provided to the reaction vessel 11. The protective gas blowing pipe 22 is made of a metal material (for example, stainless-steel) or a nonmetal material (for example, quartz) having heat resistance, corrosion resistance, and the like.

On the outside of the reaction vessel 11 in the protective gas blowing pipe 22, a protective gas supply source 22a and a valve 22b as a valve for supplying/stopping the protective gas, are provided in this order from an upstream side.

For example, a gas for suppressing desorption of a predetermined element from the surface of the substrate 100, or suppressing the processing gas in the processing chamber 12 from being brought into contact with or being supplied to the surface of the substrate 100, is blown as the protective gas from the protective gas blowing pipe 22 to the substrate 100 that exists at the second position. For example, when processing of forming a group III-V semiconductor film (for example, a GaN film) on the substrate 100 is performed, a gas (such as a group V element-containing gas, for example a gas containing NH₃ gas, etc., when a nitride semiconductor film is formed) for suppressing desorption of a group V element (for example, N-element) having a high vapor pressure from the group III-V semiconductor film, is blown as the protective gas from the protective gas blowing pipe 22 to the substrate 100 that exists at the second position.

A protective gas blowing section is mainly composed of the protective gas blowing pipe 22 and the valve 22b. It is conceivable that the protective gas supply source 22a is included in the protective gas blowing section.

### (2) Substrate Processing Step

Next, explanation is given for a substrate processing step performed as one of the semiconductor manufacturing steps according to this embodiment. This step is performed by the abovementioned substrate processing apparatus 10. Here, explanation is given for an example of forming the GaN film on the substrate 100 by a HVPE method.

First, for example, Ga solid is put (supplemented) in the vessel 14b. Then, for example a sapphire substrate as the substrate 100 is loaded into the processing chamber 12, placed on the susceptor 20, and thereafter the processing chamber 12 is airtightly held. Then, the susceptor 20 supporting the substrate 100 is moved to the first position by the moving mechanism 21. For example, the susceptor 20 is moved by the moving mechanism 21 so that the substrate 100 supported by the susceptor 20 is positioned at the first position. Thereafter, rotation of the susceptor 20 is started. The rotation of the susceptor 20 is continued until at least film formation of the GaN film described later is ended.

In order to reduce the impurity in the processing chamber 12, the atmosphere in the processing chamber 12 is vacuum-exhausted by the vacuum pump 19a, and thereafter for example N₂ gas is charged into the processing chamber 12, to thereby set the inside of the processing chamber 12 to, for example, an atmospheric pressure. For this purpose, N₂ gas is supplied into the processing chamber 12 for a certain period of time without using the vacuum pump 19a, and thereafter the inside of the processing chamber 12 may be set to a predetermined pressure (typically 0.1 to 1 atm) using the vacuum pump (or a blower) 19a. Further, the inside of the vessel 14b is heated to a predetermined temperature (for example, 600° C. to 900° C.) by the first heater 17. Thereby, the Ga solid in the vessel 14b is melted to generate a Ga melt which is the metal source 14a. Simultaneously with heating by the first heater 17, the substrate 100 that exists at the first position in the processing chamber 12 is heated to a predetermined temperature (for example, 500° C. to 1200° C.) by the second heater 18.

When the Ga melt is generated in the vessel 14b and a temperature of the substrate 100 reaches a predetermined temperature, the valve 15b is opened, and the second processing gas (for example, NH₃ gas) is supplied from the second processing gas supply pipe 15 into the processing chamber 12 and blown to the substrate 100 in the processing chamber 12.

Thereafter, the valve 13b is opened, and supply of the reaction gas (for example, HCl gas) from the reaction gas supply pipe 13 into the vessel 14b is started. Thereby, the Ga melt and the reaction gas are reacted in the vessel 14b to generate a first processing gas (for example, GaCl gas). Then, the first processing gas generated in the vessel 14b is supplied from the first processing gas supply pipe 13c into the processing chamber 12, and blown to the substrate 100 in the processing chamber 12.

Further, the valve 16b is opened at a predetermined timing, and a doping gas (for example, SiH₂Cl₂ gas) is supplied from the doping gas supply pipe 16 into the processing chamber 12 and blown to the substrate 100 in the processing chamber 12. For example, when an outermost surface of the GaN film is formed as a Si-doped layer, the valve 16b is opened when a thickness of the formed GaN film becomes a predetermined thickness, and film formation of the Si-doped layer is started. Further, for example, when an entire GaN film is formed as the Si-doped layer, the valve 16b is opened simultaneously with the valve 15b.

Then, Si-element which is an impurity is doped in the GaN film, while forming the GaN film having a predetermined thickness on the substrate 100 by making the first processing gas and the second processing gas react with each other.

After elapse of the time (film formation time) for predetermined substrate processing and when the thickness of the GaN film reaches a predetermined thickness, the susceptor 20 supporting the substrate 100 is moved to the second position by the moving mechanism 21. For example, the susceptor 20 is moved by the moving mechanism 21 so that the substrate 100 supported by the susceptor 20 is positioned at the second position in the processing chamber 12. Thereby, the processing of forming the GaN film is ended.

The valve 22b is opened before the susceptor 20 is moved to the second position. For example, simultaneously with start of moving the susceptor 20 by the moving mechanism 21, the valve 22b is opened. By moving the susceptor 20 supporting the substrate 100 to the second position, blow of the protective gas (for example, NH₃ gas) from the protective gas blowing pipe 22 to the substrate 100 (the already processed substrate 100) that exists at the second position is started.

Further, supply of the reaction gas into the vessel 14b, supply of the second processing gas into the processing chamber 12, and supply of the doping gas into the processing chamber 12 are stopped, and energization to the first heater 17 and the second heater 18 is stopped so that the temperature of the inside of the processing chamber 12 is decreased to a predetermined temperature, and thereafter the valve 22b is closed, to thereby stop supply of the protective gas. Here, the predetermined temperature is a temperature at which the surface of the substrate 100 is not altered even when the protective gas such as NH₃ gas is not supplied. For example, when the GaN film is formed on the substrate 100, the temperature is about 500° C.

Thereafter, the first processing gas, the second processing gas, and the doping gas (hereinafter, these three gases are collectively referred to as “processing gas”) remained in the processing chamber 12 are exhausted by the vacuum pump 19a. For this purpose, the processing gas remained in the processing chamber 12 may be discharged to the outside of the processing chamber 12 by supplying N₂ gas into the processing chamber 12 for a certain period of time without using the vacuum pump 19a. When discharge of the processing gas etc., is completed, an inert gas such as N₂ gas is supplied into the processing chamber 12 to set the inside of the processing chamber 12 to the atmospheric pressure. In this state, the temperature of the inside of the processing chamber 12 is decreased (cooled) to near room temperature at which the substrate 100 can be taken out. Then, the substrate 100 is detached from the susceptor 20, and the substrate 100 is unloaded to the outside of the processing chamber 12.

### (3) Effect of this Embodiment

According to this embodiment, the following one or a plurality of effects are exhibited.
(a) By providing the moving mechanism 21 that moves the susceptor 20 (substrate support section) in the processing chamber 12 between the first position to which the processing gas supplied from the processing gas supply section is blown, and the second position to which the processing gas supplied from the processing gas supply section is not blown, it is possible to suppress unintended substrate processing from being performed. For example, after predetermined substrate processing is ended, it is possible to suppress unintended substrate processing from being performed to the already processed substrate 100.
Namely, when predetermined substrate processing is ended (for example, after elapse of the time for predetermined substrate processing), it is possible to suppress blow (supply) of the processing gas remained in the processing chamber 12 to the substrate 100, by moving the susceptor 20 supporting the substrate 100 to the second position from the first position. As a result, it is possible to suppress unintended substrate processing from being performed.
For example, when predetermined substrate processing is ended and when supply of the processing gas into the processing chamber 12, that is, when supply of the reaction gas into the processing gas generator 14 and supply of the second processing gas and the doping gas into the processing chamber 12 are stopped, concentrations of the first processing gas, the second processing gas, and the doping gas in the processing chamber 12 are gradually lowered. However, the first processing gas is continuously generated in the processing gas generator 14 due to the reaction gas remained in the processing gas generator 14, and continuously supplied into the processing chamber 12 in some cases. Therefore, as the time passes from stop of supply of the processing gas into the processing chamber 12, the composition of the processing gas in the processing chamber 12, that is, the ratio of the first processing gas, the second processing gas, and the doping gas is changed gradually in some cases. Specifically, the concentrations of the second processing gas and the doping gas become lower than the concentration of the first processing gas in the processing chamber 12 in some cases. Even in such a case, by moving the susceptor 20 to the second position from the first position using the moving mechanism 21, it is possible to suppress supply of the processing gas having lower concentration of the doping gas to the substrate 100.

Thereby, it is possible to suppress formation of a transition layer having lower concentration of the impurity than a desired concentration, on the substrate 100.

Thereby, it is possible to suppress variation of the composition or change of the quality of the surface of the already processed substrate 100. For example, it is possible to suppress formation of the transition layer in which the composition in a thickness direction of the film and a film thickness, etc., are not constant, on the surface of the already processed substrate 100.

Conventionally, there is a substrate processing apparatus including a moving mechanism for moving a substrate in a processing chamber. However, the moving mechanism included in the conventional substrate processing apparatus, moves the substrate (susceptor supporting the substrate) to a transport position in the processing chamber for transporting the substrate to the outside of the processing chamber from a processing position of the substrate. For example, the moving mechanism included in the conventional substrate processing apparatus, moves the substrate to a takeout position after the inside of the processing chamber is set in a high temperature atmosphere, and substrate processing performed by heating the substrate to a high temperature is ended, and the temperature of the inside of the processing chamber and the substrate is decreased to near the room temperature. Namely, the moving mechanism of the conventional substrate processing apparatus does not move the substrate to the position to which the processing gas is not blown, from the position to which the processing gas is blown. Accordingly, in the conventional substrate processing apparatus, from the moment when predetermined substrate processing is stopped, the substrate stays at the processing position of the substrate for a considerably long period of time during decrease of the temperature (cooling) of the inside of the processing chamber and the substrate in the processing chamber. Therefore, in the conventional substrate processing apparatus, it is impossible to obtain the effect of suppressing unintended substrate processing from being performed as described in this embodiment.
(b) This embodiment is particularly effective when the substrate processing apparatus 10 includes the processing gas generator 14. Namely, this embodiment is particularly effective when substrate processing is performed while generating the processing gas (first processing gas).

When predetermined substrate processing is ended and after supply of the reaction gas into the vessel 14b is stopped, the first processing gas is continuously generated due to the reaction of the reaction gas remained in the vessel 14b and the metal source 14a, and is continuously supplied into the processing chamber 12. For example, even in such a case, by moving the susceptor 20 to the second position from the first position using the moving mechanism 21, it is possible to suppress blow of the first processing gas to the already processed substrate 100. Thereby, it is possible to surely suppress unintended substrate processing from being performed. For example, in a film formation processing by the HYPE apparatus, it is possible to easily and surely control the composition and the film thickness of the formed film. Accordingly, the effect of the abovementioned (a) can be surely obtained.
(c) Further, substrate processing can be surely ended at a predetermined timing by moving the susceptor 20 supporting the substrate 100 to the second position from the first position using the moving mechanism 21, for example before supply of the processing gas from the processing gas supply section into the processing chamber 12 is stopped, or before the supply conditions are varied, such as the concentration and the composition of the processing gas supplied from the processing gas supply section (for example, the first processing gas supplied from the processing gas supply section 14 into the processing chamber 12). Namely, an end point of substrate processing can be easily and surely controlled. Thereby, the effects of the abovementioned (a) and (b) can be more surely obtained.
(d) The surface of the substrate 100 that exists at the second position can be protected by blowing the protective gas from the protective gas blowing section to the substrate 100 moved to the second position. For example, when the GaN film is formed on the substrate 100, desorption of N-element from the GaN film can be suppressed. Further, it is possible to more surely suppress supply of the processing gas in the processing chamber 12 to the substrate 100 that exists at the second position. Accordingly, it is more surely suppress variation of the composition and change of the quality of the surface of the already processed substrate 100.
(e) This embodiment is particularly effective when a film in which the impurity is doped, is formed on the substrate 100, and it is possible to more surely suppress variation of the composition and change of the quality of the surface of the already processed substrate 100.
(f) Further, Si is eluted from a quartz component constituting the substrate processing apparatus 10 in some cases. After supply of the processing gas into the processing chamber 12 is stopped, the concentration of the processing gas (the first processing gas, the second processing gas, and the doping gas) in the processing chamber 12 is gradually lowered in some cases as described above. Therefore, when Si is eluted from the quartz component constituting the substrate processing apparatus 10, the Si— concentration in the processing gas of the inside of the processing chamber 12 becomes gradually higher in some cases. Even in such a case, after predetermined substrate processing is ended, by moving the susceptor 20 to the second position from the first position using the moving mechanism 21, it is possible to suppress supply of the processing gas having higher Si-concentration as described above, to the already processed substrate 100. Thereby, it is possible to suppress formation of the transition layer having higher concentration of the impurity than a desired concentration, on the substrate 100.

Incidentally, while substrate processing is performed, namely, while the processing gas is supplied into the processing chamber 12, even when Si eluted from the quartz component constituting the substrate processing apparatus 10 is mixed in the processing gas in the processing chamber 12, the concentration of Si in this case can be ignored.

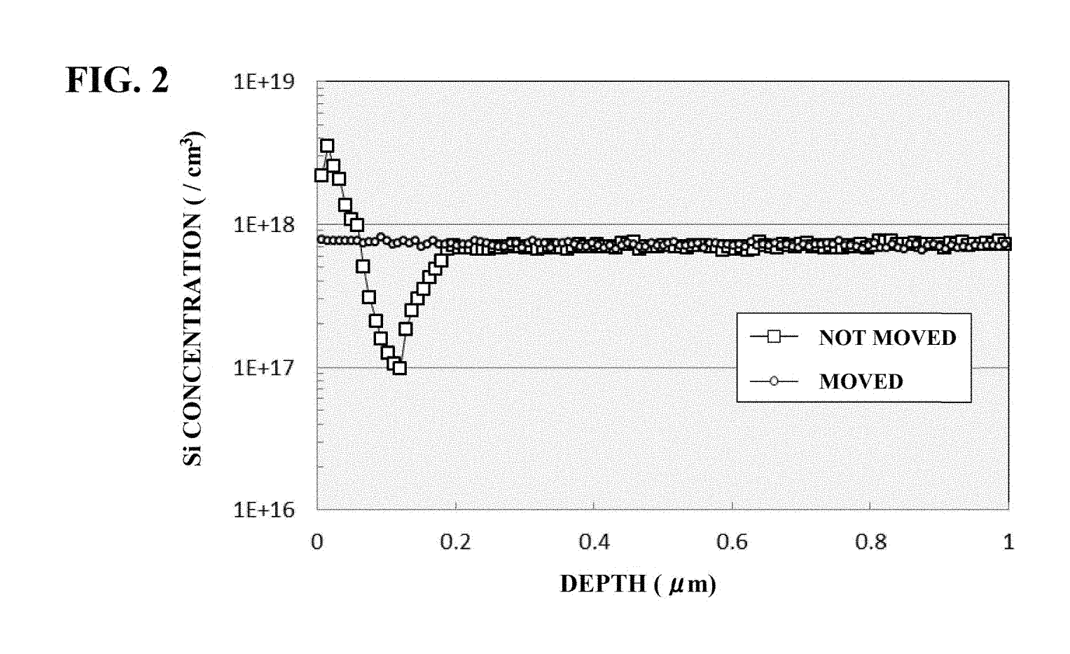

FIG. 2 is a graph (Secondary Ion Mass Spectrometry (SIMS) measurement result) showing an example of a relationship between a distance from the surface of the Si-doped GaN film and the Si-concentration, Si being an impurity and the Si-doped GaN film being formed on the substrate 100. In FIG. 2, “Moved” means that, after formation of the GaN film having a predetermined film thickness, the susceptor 20 supporting the already processed substrate 100 is moved to the second position from the first position by the moving mechanism 21. Further, “Not moved” means that the susceptor 20 supporting the substrate 100 is maintained at the first position even after formation of the GaN film having a predetermined film thickness. Further, in FIG. 2, a depth of 0 μm indicates an outermost surface of the GaN film formed on the substrate 100, when the value of the depth becomes larger, this means that the distance from the surface of the GaN film becomes longer.

From FIG. 2, it is confirmed that when the susceptor 20 is moved by the moving mechanism 21 after predetermined substrate processing is ended, variation of a silicon-concentration in the surface of the substrate 100 can be suppressed. Namely, it is confirmed that the impurity concentration in the GaN film formed on the already processed substrate 100 is substantially constant in the thickness direction. For example, it is confirmed that formation of the transition layer on the already processed substrate 100 can be suppressed.

In contrast, it is confirmed that when the susceptor 20 supporting the substrate 100 is not moved to the second position after predetermined substrate processing, the composition in the surface of the substrate 100 is varied in some cases. Namely, it is confirmed that the Si-concentration in the outermost surface of the GaN film formed on the already processed substrate 100 is varied in some cases. For example, it is confirmed that the transition layer having a thickness of about 0.2 μm is formed on the already processed substrate 100 in some cases. It is also confirmed that the Si-concentration becomes gradually lower from a position of about 0.2 μm to a position of about 0.1 μm from the surface of the transition layer. Namely, it can be confirmed that the composition of the processing gas in the processing chamber 12 is varied. Specifically, it can be confirmed that even after supply of the reaction gas into the processing gas generator 14 is stopped, the first processing gas is continuously generated due to the reaction gas remained in the processing gas generator 14, and the first processing gas is continuously supplied into the processing chamber 12. Further, it can be confirmed that the Si-concentration becomes gradually higher from the position of about 0.1 μm to the outermost surface, from the surface of the transition layer. This is an influence of Si eluted from the quartz component constituting the substrate processing apparatus 10.

### Other Embodiment

As described above, an embodiment of the present invention has been specifically described. However, the present invention is not limited to the abovementioned embodiments, and various modifications can be made without departing from the gist of the invention.

In the abovementioned embodiment, when predetermined substrate processing is ended and after the susceptor 20 supporting the substrate 100 is moved to the second position from the first position by the moving mechanism 21, supply of the processing gas into the processing chamber 12 (for example, supply of the reaction gas into the processing gas generator 14, supply of the second processing gas and the doping gas into the processing chamber 12) is stopped. However, the present invention is not limited thereto. For example, supply of the processing gas into the processing chamber 12 may be stopped simultaneously with start of moving the susceptor 20 supporting the substrate 100 by the moving mechanism 21. Further, when predetermined substrate processing is ended and after supply of the processing gas into the processing chamber 12 is stopped, movement of the susceptor 20 supporting the substrate 100 using the moving mechanism 21 may be started.

In the abovementioned embodiment, supply of the protective gas from the protective gas supply section is started simultaneously with start of moving the susceptor 20 supporting the substrate 100 by the moving mechanism 21. However, the present invention is not limited thereto. The protective gas may be continuously supplied from the protective gas supply section before the movement of the susceptor 20 supporting the substrate 100 by the moving mechanism 21 is started, namely when the susceptor 20 supporting the substrate 100 exists at the first position. For example, the protective gas may be continuously supplied from the protective gas supply section, even during substrate processing performed in the processing chamber 12.

In the abovementioned embodiment, the movement of the susceptor 20 by the moving mechanism 21 is controlled through the controller electrically connected to the moving mechanism 21. However, the present invention is not limited thereto. For example, the movement of the susceptor 20 by the moving mechanism 21 may be performed by a person.

In the abovementioned embodiment, explanation has been given for the substrate processing apparatus 10 including the processing gas generator 14. However, the present invention is not limited thereto. Even in a case of a substrate processing apparatus not including the processing gas generator 14, it is possible to obtain the effects of the abovementioned (a) and (b), etc.

Further as shown in FIG. 1, in the abovementioned embodiment, the susceptor 20 is provided so that the surface of the substrate 100 is disposed vertically to a supply direction of the first processing gas, the second processing gas, and the doping gas (processing gas) into the processing chamber 12. However, the present invention is not limited thereto. For example, the susceptor 20 may be provided so that the surface of the substrate 100 is disposed in parallel to the supply direction of the processing gas into the processing chamber 12.

In the abovementioned embodiment, explanation has been given for a case that the Ga melt obtained by melting for example Ga solid at a high temperature is used as the metal source 14a. However, the present invention is not limited thereto. A source which is liquid at ordinary temperature or a source which is solid at high temperature may be used as the metal source 14a.

In the abovementioned embodiment, explanation has been given for a case that the processing gas generator 14 is provided in the processing chamber 12. However, the present invention is not limited thereto. For example, the processing gas generator 14 may be provided on the outside of the processing chamber 12 (reaction vessel 11) of the substrate processing apparatus 10. In this case, a heater for heating the inside of the vessel 14b, which is included in the processing gas generator 14, to a predetermined temperature may be provided on the outer periphery of the processing gas generator 14.

In the abovementioned embodiment, explanation has been given for a case that the substrate processing apparatus 10 is the HVPE apparatus. However, the present invention is not limited thereto. For example, even in a case that the substrate processing apparatus 10 is an MOVPE apparatus, the effects of the abovementioned (a) and (b), etc., can be obtained. However, in the case of the HVPE apparatus in which control of the film thickness and the film formation rate is more difficult than the MOVPE apparatus, the present invention can sufficiently exert the effects of the abovementioned (a) and (b), etc.

Further, in the abovementioned embodiment, explanation has been given for the processing of forming the GaN film as substrate processing. However, the present invention is not limited thereto. In addition, the present invention can also be applied to a substrate processing apparatus that performs film formation processing of forming various films such as an oxide film and a metal film, and performs etching treatment, etc., as substrate processing, and a substrate processing apparatus that manufactures a substrate by performing the abovementioned substrate processing. Also thereby, the effects of the abovementioned (a) and (b), etc., can be obtained.

### Preferable Aspects of the Present Invention

Preferable aspects of the present invention will be supplementarily described hereafter.

### [Supplemental Description 1]

According to an aspect of the present invention, there is provided a substrate processing apparatus, including:

a processing chamber in which a substrate is processed;

a substrate support section that supports the substrate in the processing chamber;

a processing gas supply section that supplies a processing gas into the processing chamber; and

a moving mechanism that moves the substrate support section in the processing chamber, between a first position to which the processing gas supplied from the processing gas supply section is blown, and a second position to which the processing gas supplied from the processing gas supply section is not blown.

### [Supplemental Description 2]

Preferably, there is provided the substrate processing apparatus of the supplementary description 1, wherein the moving mechanism moves the substrate support section supporting the substrate to the second position after substrate processing is ended and before supply of the processing gas from the processing gas supply section into the processing chamber is stopped.

### [Supplemental Description 3]

Preferably, there is provided the substrate processing apparatus of the supplementary description 1 or 2, wherein the moving mechanism moves the substrate support section supporting the substrate to the second position after substrate processing is ended and before supply conditions of the processing gas supplied from the processing gas supply section are varied.

### [Supplemental Description 4]

Preferably, there is provided the substrate processing apparatus of any one of the supplementary descriptions 1 to 3, wherein substrate processing is stopped by moving the substrate support section supporting the substrate to the second position using the moving mechanism.

### [Supplemental Description 5]

Preferably, there is provided the substrate processing apparatus of any one of the supplementary descriptions 1 to 4, including a controller that controls the moving mechanism.

### [Supplemental Description 6]

Preferably, there is provided the substrate processing apparatus of any one of the supplementary descriptions 1 to 5, wherein the processing gas supply section includes a processing gas generator that generates a processing gas by making a metal source and a reaction gas react with each other.

### [Supplemental Description 7]

Preferably, there is provided the substrate processing apparatus of the supplementary description 6,

wherein the metal source is a metal source containing a group III element, and

the processing gas generated in the processing gas generator is a group III element-containing gas.

### [Supplemental Description 8]

Preferably, there is provided the substrate processing apparatus of the supplementary description 6 or 7, wherein the processing gas supply section includes a group V element-containing gas supply section that supplies a group V element-containing gas as a processing gas.

### [Supplemental Description 9]

Preferably, there is provided the substrate processing apparatus of any one of the supplementary descriptions 1 to 8, including a protective gas blowing section for blowing a protective gas that protects a surface of an already processed substrate, to the already processed substrate moved to the second position.

### [Supplemental Description 10]

Preferably, there is provided the substrate processing apparatus of any one of the supplementary descriptions 1 to 9, wherein when processing of forming a film on the substrate is performed as substrate processing, a doping gas supply section is provided, which supplies a doping gas for an impurity to be doped in the film

### [Supplemental Description 11]

There is provided a substrate processing method, including a step of:

processing a substrate in a processing chamber,

wherein in the step of processing the substrate, substrate processing is performed by blowing a processing gas from a processing gas supply section, to the substrate that exists at a first position to which the processing gas is blown, the processing gas being supplied into the processing chamber from the processing gas supply section, and

substrate processing is ended by moving a substrate support section supporting the substrate using a moving mechanism, to a second position to which the processing gas is not blown, the processing gas being supplied into the processing chamber from the processing gas supply section.

### [Supplemental Description 12]

Preferably, there is provided the substrate processing method of the supplementary description 11, including a step of:

blowing a protective gas that protects a surface of an already processed substrate moved to the second position, from a protective gas blowing section.

### DESCRIPTION OF SIGNS AND NUMERALS

10 Substrate processing apparatus
12 Processing chamber
14 Processing gas generator
20 Susceptor
21 Moving mechanism

1. A substrate processing apparatus, comprising:
a processing chamber in which a substrate is processed;
a substrate support section that supports the substrate in the processing chamber;
a processing gas supply section that supplies a processing gas into the processing chamber; and
a moving mechanism that moves the substrate support section in the processing chamber, between a first position to which the processing gas supplied from the processing gas supply section is blown, and a second position to which the processing gas supplied from the processing gas supply section is not blown.

2. The substrate processing apparatus according to claim 1, wherein the moving mechanism moves the substrate support section supporting the substrate to the second position after substrate processing is ended and before supply of the processing gas from the processing gas supply section into the processing chamber is stopped.

3. The substrate processing apparatus according to claim 1, wherein the moving mechanism moves the substrate support section supporting the substrate to the second position after substrate processing is ended and before supply conditions of the processing gas supplied from the processing gas supply section are varied.

4. The substrate processing apparatus according to claim 1, wherein the processing gas supply section comprises a processing gas generator that generates a processing gas by making a metal source and a reaction gas react with each other.

5. The substrate processing apparatus according to claim 1, comprising a protective gas blowing section for blowing a protective gas that protects a surface of an already processed substrate, to the already processed substrate moved to the second position.

6. The substrate processing apparatus according to claim 1, wherein when processing of forming a film on the substrate is performed as substrate processing, a doping gas supply section is provided, which supplies a doping gas for an impurity to be doped in the film.

7. A substrate processing method, comprising a step of:
processing a substrate in a processing chamber,
wherein in the step of processing the substrate, substrate processing is performed by blowing a processing gas from a processing gas supply section, to the substrate that exists at a first position to which the processing gas is blown, the processing gas being supplied into the processing chamber from the processing gas supply section, and
substrate processing is ended by moving a substrate support section supporting the substrate using a moving mechanism, to a second position to which the processing gas is not blown, the processing gas being supplied into the processing chamber from the processing gas supply section.
